(19) United States
(12) Patent Application Publication
(10) Pub. No.: US 2007/0262410 A1
(43) Pub. Date: Nov. 15, 2007

(54) SEMICONDUCTOR DEVICE AND METHOD FOR MANUFACTURING

(75) Inventors: Syotaro Ono, Kanagawa-ken (JP); Yusuke Kawaguchi, Kanagawa-ken (JP); Yoshihiro Yamaguchi, Saitama-ken (JP); Miwako Akiyama, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/742,133

(22) Filed: Apr. 30, 2007

(30) Foreign Application Priority Data
May 1, 2006 (JP) 2006-127245

(51) Int. Cl. H01L 29/00

(52) U.S. Cl. 257/499

(57) ABSTRACT

A semiconductor device includes: a semiconductor layer of a first conductivity type, a plurality of trenches provided on a major surface side of the semiconductor layer, an insulating film provided on an inner wall surface and on top of the trench, a conductive material surrounded by the insulating film and filling the trench, a first semiconductor region of a second conductivity type provided between the trenches, a second semiconductor region of the first conductivity type provided in a surface portion of the first semiconductor region, a mesa of the semiconductor layer provided between the trenches of a Schottky barrier diode region adjacent to a transistor region including the first semiconductor region and the second semiconductor region, a control electrode connected to the conductive material filling the trench of the transistor region and a main electrode provided in contact with a surface of the first semiconductor region, the second semiconductor region, a surface of the mesa and a part of the conductive material filling the trench of the Schottky barrier diode region. The part is exposed through the insulating film.

### CROSS-REFERENCE TO RELATED APPLICATION

This application is based upon and claims the benefit of priority from the prior Japanese Patent Application No. 2006-127245, filed on May 1, 2006; the entire contents of which are incorporated herein by reference.

### BACKGROUND OF THE INVENTION

1. Field of the Invention

This invention relates to a semiconductor device and a method for manufacturing the same, and more particularly to a semiconductor device having a trench gate structure and a method for manufacturing the same.

2. Background Art

The trench gate structure, in which trenches are formed in a semiconductor surface and filled with gate electrodes, is applied to semiconductor devices such as IGBT (Insulated Gate Bipolar Transistor) and MOSFET (Metal Oxide Semiconductor Field Effect Transistor), and mainly used in power applications.

A MOSFET having a trench gate structure has a larger current capability and a lower ON resistance than a DMOSFET (Double diffused MOSFET), and is promising for cost reduction by chip shrink. Furthermore, a MOSFET having a trench gate structure can achieve a breakdown voltage of tens to hundreds of volts, and hence is being widely used for a switching power supply in mobile terminals and personal computers.

Recently, with the increasing speed of CPU (Central Processing Unit) in personal computers, for example, it is desired to increase the switching frequency and efficiency of the associated power supply system (e.g. DC-DC converter power supply) itself. In such a step-down DC-DC converter power supply, a MOSFET is used as a switching (chopping) element. Typically, a flywheel diode is used to avoid interrupting the current on the load side during interruption of current from the primary side to the secondary side due to switching. However, as the output voltage required on the load side becomes lower, the forward voltage drop of the above diode becomes not negligible. Hence, in another configuration also in use, the source-drain junction of another MOSFET (second MOSFET) is used instead of the diode, and turned on for the same period as the conducting period of the diode. A trench gate MOSFET is a typical MOSFET with low breakdown voltage used for such application.

In the above configuration, it is difficult to control the gate voltage so that the second MOSFET is turned on for exactly the same period as the conducting period of the diode. Hence, in practical use, there is a period in which the first MOSFET and the second MOSFET are both turned off (dead time). During this dead time, the built-in PN diode, which exists in the second MOSFET as a parasite element, is turned on. Although this period is controlled to be as short as possible, the forward voltage drop of the above built-in PN diode causes loss to the power supply system. Hence, in order to reduce the loss of the power supply system due to the forward voltage drop during the dead time, a Schottky barrier diode having a smaller forward voltage drop than the above built-in PN diode is connected parallel to the second MOSFET (see, e.g., JP 2004-511910T). Using a Schottky barrier diode rather than a PN diode has the advantage of reducing the above forward voltage drop and reducing the electric charge loss at reverse recovery time by preventing hole injection during the forward conducting time.

Such a Schottky barrier diode is typically connected as a component separate from the second MOSFET, but may be embedded in the second MOSFET by taking advantage of the DC-DC converter configuration. Such embedding enables extra parasite inductance in the Schottky barrier diode and the MOSFET to be decreased. If any parasite inductance exists between the Schottky barrier diode and the MOSFET, application of a diode forward voltage (here, application to the anode side of the MOSFET built-in PN diode and the Schottky barrier diode connected in parallel) activates the PN diode of the MOSFET before the operation of the Schottky barrier diode, and causes the above hole injection. Reducing the parasite inductance is important for activating only the Schottky barrier diode without activating the PN diode during the dead time. The technique of reducing interconnect inductance by embedding a Schottky barrier diode in a MOSFET chip is crucial.

However, it is necessary to reduce the cost of embedding a Schottky barrier diode in a MOSFET. Embedding a Schottky barrier diode should avoid increasing the area of the MOSFET or Schottky barrier diode relative to the conventional one. The increase of manufacturing cost due to complicated processes for fabrication on the same chip should also be avoided.

### SUMMARY OF THE INVENTION

According to an aspect of the invention, there is provided a semiconductor device including: a semiconductor layer of a first conductivity type; a plurality of trenches provided on a major surface side of the semiconductor layer; an insulating film provided on an inner wall surface and on top of the trench; a conductive material surrounded by the insulating film and filling the trench; a first semiconductor region of a second conductivity type provided between the trenches; a second semiconductor region of the first conductivity type provided in a surface portion of the first semiconductor region; a mesa of the semiconductor layer provided between the trenches of a Schottky barrier diode region adjacent to a transistor region including the first semiconductor region and the second semiconductor region; a control electrode connected to the conductive material filling the trench of the transistor region; and a main electrode provided in contact with a surface of the first semiconductor region, the second semiconductor region, a surface of the mesa and a part of the conductive material filling the trench of the Schottky barrier diode region, the part being exposed through the insulating film.

According to other aspect of the invention, there is provided a method for manufacturing a semiconductor device including: forming a plurality of trenches on a major surface side of a semiconductor layer of a first conductivity type; forming a first insulating film on an inner wall surface of the trench; burying a conductive material in the trench with the first insulating film formed on the inner wall surface; forming a first semiconductor region of a second conductivity type between the trenches of a transistor region; forming a second semiconductor region of the first conductivity type in a surface portion of the first semiconductor region; partially exposing the conductive material of a Schottky barrier diode region adjacent to the transistor region and forming a second insulating film overlying the conductive material in the trench; and forming a main electrode in contact with a surface of the second semiconductor region, the partially exposed conductive material in the Schottky barrier diode region, and the semiconductor layer between the trenches of the Schottky barrier diode region.

According to other aspect of the invention, there is provided a method for manufacturing a semiconductor device including: forming a plurality of trenches on a major surface side of a semiconductor layer of a first conductivity type; forming a first insulating film on an inner wall surface of the trench; burying a conductive material in the trench with the first insulating film formed on the inner wall surface; forming a first semiconductor region of a second conductivity type between the trenches of a transistor region; forming a second semiconductor region of the first conductivity type in a surface portion of the first semiconductor region; forming a second insulating film overlying the conductive material in the trench; forming a contact groove crossing the trench of a Schottky barrier diode region adjacent to the transistor region so as to expose the first semiconductor region through the second semiconductor region and to expose the conductive material of the Schottky barrier diode region through the second insulating film; and forming a main electrode that fills the contact groove and is in contact with a surface of the semiconductor layer between the trenches of the Schottky barrier diode region.

### BRIEF DESCRIPTION OF THE DRAWINGS

FIG. 1 is a schematic view illustrating the main part of a semiconductor device according to a first example of the invention.

FIG. 2 is a schematic diagram illustrating the circuit configuration of a step-down DC-DC converter.

FIGS. 3 to 5 are process cross-sectional views illustrating the main part of a process for manufacturing a semiconductor device according to the first example.

FIG. 6 is a schematic view illustrating the main part of a semiconductor device according to a second example of the invention.

FIGS. 7 and 8 are process cross-sectional views illustrating the main part of a process for manufacturing a semiconductor device according to the second example.

FIG. 9 is a schematic view illustrating the main part of a semiconductor device according to a variation of the invention.

FIG. 10 is a schematic view illustrating the main part of a semiconductor device according to a comparative example.

FIG. 11 is the same as FIG. 10 except that the first main electrode is partially removed.

FIG. 12 is a graph showing the relationship between the width of the semiconductor mesa and the output charge of a Schottky barrier diode.

### DETAILED DESCRIPTION OF THE INVENTION

### First Example

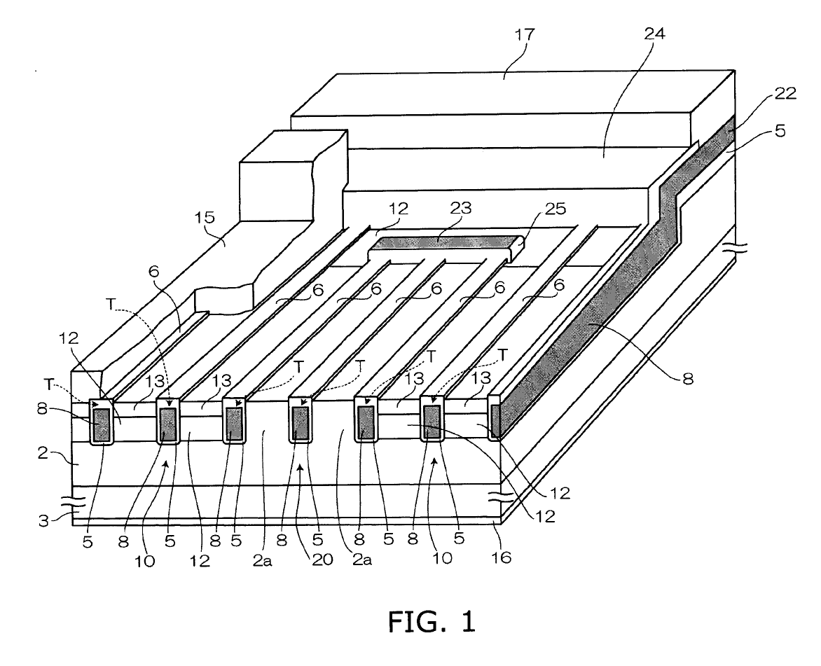

FIG. 1 is a schematic view illustrating the main part of a semiconductor device according to a first example of the invention.

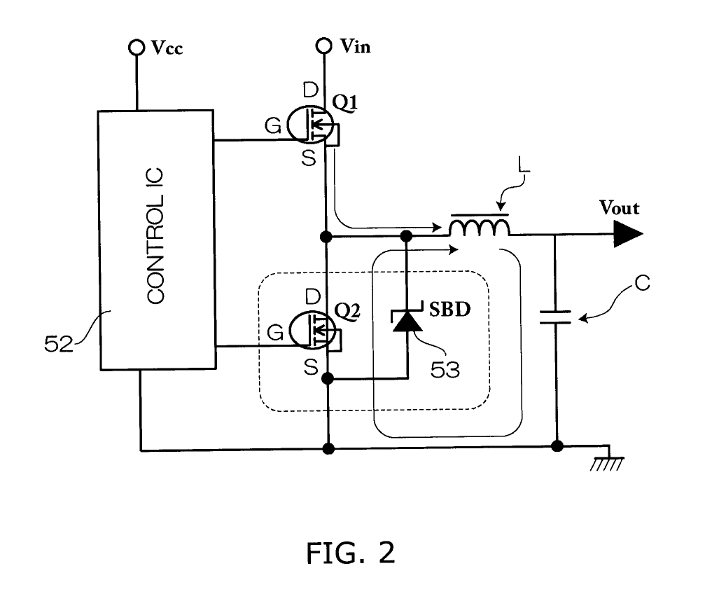

FIG. 2 is a schematic diagram illustrating the circuit configuration of a DC-DC converter based on the semiconductor device according to the embodiment of the invention. The semiconductor device shown in FIG. 1 corresponds to the configuration enclosed by the dashed line in FIG. 2 (a transistor Q2 and a Schottky barrier diode 53).

Before the description of the semiconductor device according to the embodiment, the DC-DC converter shown in FIG. 2 is briefly described.

This DC-DC converter is a non-isolated step-down DC-DC converter, where an input voltage Vin is applied from the input terminal (primary side) and an output voltage Vout lower than the input voltage Vin is produced at the output terminal (secondary side).

The drain of the transistor Q1 is connected to the input terminal, and the gate of the transistor Q1 is connected to a control IC 52. The transistor Q1 receives a gate driving signal from the control IC 52 and serves as a switching element. The source of the transistor Q1 is connected to the drain of the transistor Q2.

The source of the transistor Q2 is connected to ground. The gate of the transistor Q2 is connected to the control IC 52. The transistor Q2 receives a gate driving signal from the control IC 52 and serves as a switching element.

The connection node between the source of the transistor Q1 and the drain of the transistor Q2 is connected to the cathode of the Schottky barrier diode 53. The anode of the Schottky barrier diode 53 is connected to the source of the transistor Q2 (ground). That is, the transistor Q2 and the Schottky barrier diode 53 are parallel connected.

The connection node between the source of the transistor Q1 and the drain of the transistor Q2 is also connected to the output terminal through an inductor L. A capacitor C is connected between the output terminal and ground. The inductor L and the capacitor C constitute a low-pass filter. To control the ON/OFF of the transistors Q1 and Q2, gate input signals with nearly inverted phases are generated by the control IC 52 and supplied to the gates of the transistors Q1 and Q2, respectively. If both switches (transistors Q1 and Q2) are simultaneously turned on, a very large current flows from the input terminal through the transistors Q1 and Q2 to ground. To avoid this, for example, turning off the transistor Q1 is followed by a short elapsed time before turning on the transistor Q2.

The voltage ratio between the input voltage Vin and the output voltage Vout can be configured by the duty ratio of switching (chopping) at the transistor Q1. While the transistor Q1 is turned on, a current flows through the transistor Q1 to the inductor L where energy is accumulated. During the time from turning off the transistor Q1 to turning on the transistor Q2, the energy accumulated in the inductor L (back electromotive force) causes a flywheel current to flow from ground through the transistor Q2 and the Schottky barrier diode 53.

When the transistor Q1 is turned off, a flywheel current can be obtained simply by providing the Schottky barrier diode 53, and the transistor Q2 is not necessarily needed. However, when the output voltage required on the secondary side is low, the forward voltage drop of the Schottky barrier diode 53 becomes not negligible and needs voltage reduction. Hence a transistor Q2 is provided, which is turned on/off in a nearly inverted phase with the ON/OFF of the transistor Q1.

The phases at which the transistors Q1 and Q2 are turned on/off are configured so that, strictly, there is a short period in which both of them are turned off. This is intended for avoiding a period in which the transistors Q1 and Q2 are short-circuited. However, during the period in which the transistors Q1 and Q2 are both turned off (dead time), the built-in body diode, which is structurally included in the transistor Q2 as a parasite element, is typically turned on. The forward voltage drop of this diode is not negligible.

Hence a Schottky barrier diode is parallel connected between the source and the drain of the transistor Q2. Thus the source-drain voltage of the transistor Q2 can be effectively reduced during the dead time. More specifically, during the dead time, the built-in body diode of the transistor Q2 is prevented from being turned on, and the current can be passed through the Schottky barrier diode 53 having a lower forward voltage drop. Furthermore, it is possible to reduce the circuit loss due to the output charge when a reverse blocking voltage is applied.

In this embodiment, the elements enclosed by the dashed line in FIG. 2 are combined on a single semiconductor chip. One-chip implementation of the transistor Q2 and the Schottky barrier diode 53 can reduce delay caused by the parasite inductance due to the chip-to-chip interconnect (the activation of the built-in PN diode of the MOSFET before the activation of the Schottky barrier diode) as compared with the case where the transistor Q2 and the Schottky barrier diode 53 in different chips are parallel connected.

The foregoing has described the DC-DC converter based on the semiconductor device of this embodiment.

Next, the semiconductor device shown in FIG. 1 is described in detail.

The semiconductor device according to this example comprises a MOS (Metal Oxide Semiconductor) transistor formed in a transistor region 10 and a Schottky barrier diode formed in a Schottky barrier diode region 20 adjacent to the transistor region 10.

The semiconductor device according to this embodiment has a laminated structure of a semiconductor layer 2 illustratively made of n⁻-type silicon and a semiconductor layer 3 illustratively made of n⁺-type silicon. The n⁺-type semiconductor layer 3 serves as a drain layer in the MOS transistor.

A plurality of trenches T are provided on the major surface side of the n⁻-type semiconductor layer 2. The depth direction of each trench T is generally perpendicular to the major surface of the semiconductor layer 2. The plurality of trenches T extend parallel to each other in a striped configuration.

An insulating film 5 is formed on the inner wall surface (bottom surface and sidewall surface) of each trench T. A conductive material 8 illustratively made of polysilicon is buried in the trench T via the insulating film 5.

An insulating film 6 is provided on top of the trench T so as to overlie the conductive material 8. More specifically, the space inside the trench T surrounded by the insulating films 5 and 6 is filled with the conductive material 8. The insulating films 5 and 6 are illustratively made of silicon oxide. The insulating film 5 in the transistor region 10 serves as a gate insulating film.

A base region (first semiconductor region) 12 illustratively made of p-type silicon is formed between adjacent trenches T in the transistor region 10. A source region (second semiconductor region) 13 illustratively made of n⁺-type silicon is formed in the surface portion of the base region 12.

In the Schottky barrier diode region 20, the base region 12 and the source region 13 are not formed between adjacent trenches T, but the semiconductor layer 2 is provided between the trenches T like a mesa.

The conductive material 8 inside the trench T in the transistor region 10 is connected to an extraction portion 22 provided at one end of the trench extending direction. An insulating film 24 is provided on the extraction portion 22, and the extraction portion 22 is partially exposed through the insulating film 24. A control electrode 17 is provided in contact with the exposed portion of the extraction portion 22, and hence the conductive material 8 filling the trench T of the transistor region 10 is electrically connected to the control electrode 17. The control electrode 17 serves as a gate electrode of the MOS transistor.

The end of the trench T adjacent to the semiconductor mesa 2a of the Schottky barrier diode region 20 is located, in FIG. 1, on the front side of the above extraction portion 22 and insulating film 24. The conductive material 8 filling the trench T adjacent to the semiconductor mesa 2a is connected to an extraction portion 23 provided, in FIG. 1, on the front side of the above extraction portion 22 and insulating film 24. The extraction portion 23 extends in a direction generally orthogonal to the extending direction of the trench T so as to cross the trench T of the Schottky barrier diode region 20. The extraction portion 23 is surrounded by an insulating film 25 and its upper surface is exposed through the insulating film 25. The extraction portion 23 of the conductive material 8 in the Schottky barrier diode region 20 is insulatively isolated from the extraction portion 22 of the conductive material 8 in the transistor region 10.

A first main electrode 15 forms an ohmic contact with the source region 13 of the MOS transistor to serve as a source electrode of the MOS transistor, and forms a Schottky contact with the surface of the mesa 2a of the semiconductor layer 2 of the Schottky barrier diode to also serve as an anode electrode of the Schottky barrier diode.

Furthermore, the first main electrode 15 is also in contact with the extraction portion 23 of the conductive material 8 of the Schottky barrier diode region 20, and thereby the conductive material 8 in the trench T of the Schottky barrier diode region 20 is placed at the source potential of the MOS transistor. If the conductive material 8 in the trench T of the Schottky barrier diode region is connected to the gate electrode, the gate-drain capacitance increases. This causes concern about the increase of the drive loss and the loss due to shoot-through current between the transistor Q1, Q2 and ground in the above DC-DC converter. However, according to this embodiment, the above losses can be prevented by connecting the conductive material 8 in the trench T of the diode region 20 to the first main electrode 15 placed at the source potential.

An interlayer insulating film, not shown, is interposed between the first main electrode 15 and the control electrode 17, and insulatively isolates the first main electrode 15 from the control electrode 17.

A second main electrode 16 is formed on the surface of the semiconductor layer 3 opposite to the surface where the semiconductor layer 2 is provided. The second main electrode 16 serves as a drain electrode of the MOS transistor, and also serves as a cathode electrode of the Schottky barrier diode.

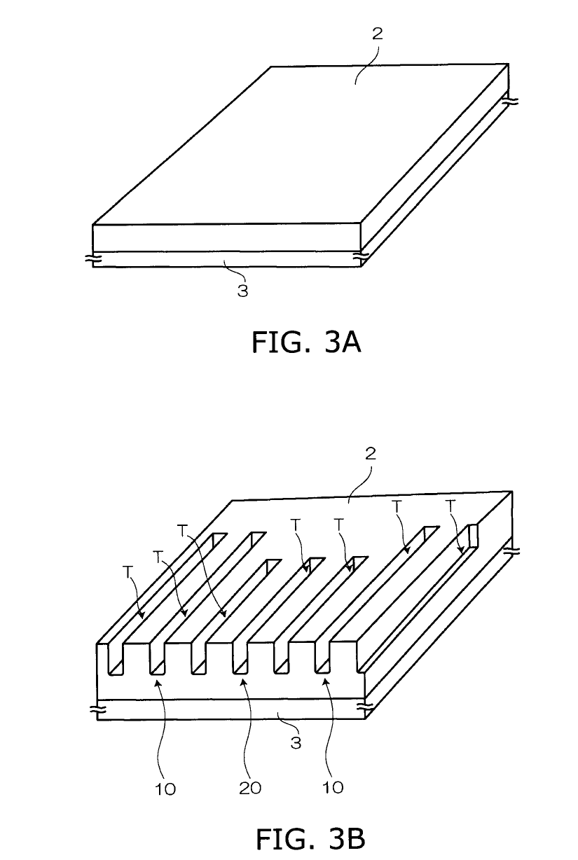

Next, an example method for manufacturing a semiconductor device according to the first example of the invention is described. FIGS. 3 to 5 are process cross-sectional views illustrating the main part of a process for manufacturing a semiconductor device according to the first example.

As shown in FIG. 3A, a laminated structure of a semiconductor layer 3 made of n⁺-type silicon and a semiconductor layer 2 made of n⁻-type silicon, for example, is manufactured. Then, as shown in FIG. 3B, a plurality of trenches T are formed in the surface of the semiconductor layer 2 by e.g. RIE (Reactive Ion Etching). The length in the extending direction (longitudinal direction) of the trench T formed in the Schottky barrier diode region 20 is made shorter than the length in the extending direction (longitudinal direction) of the trench T formed in the transistor region 10 so that the end of the trench T formed in the Schottky barrier diode region 20 is located inner than the end of the trench T formed in the transistor region 10.

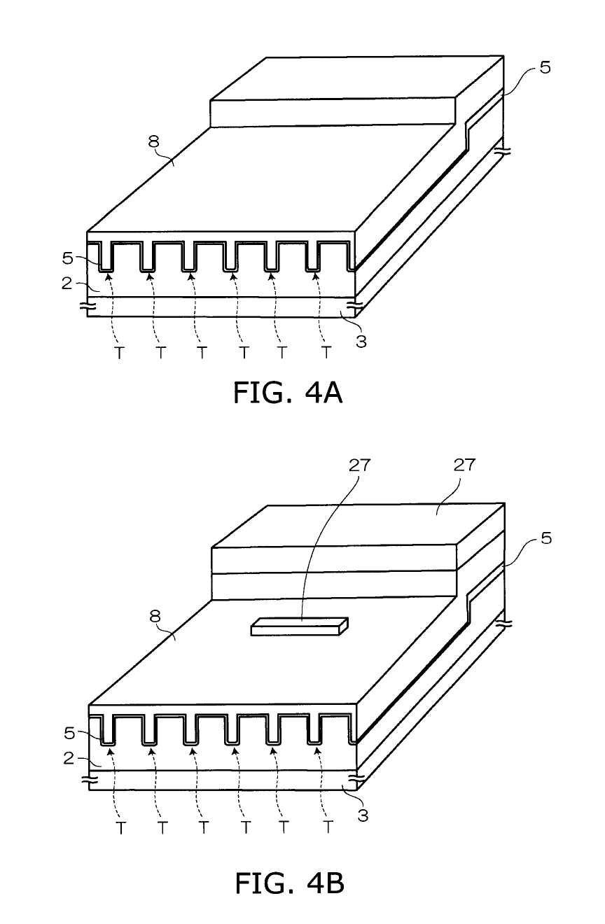

Next, as shown in FIG. 4A, an insulating film (silicon oxide film) 5 is formed on the surface of the semiconductor layer 2 and the inner wall surface (bottom surface and sidewall surface) of each trench T by e.g. thermal oxidation. Then a conductive material 8 made of polysilicon is deposited on the entire surface of the semiconductor layer 2 by e.g. CVD (Chemical Vapor Deposition) so as to fill the trench T.

Next, a resist is formed on the entire surface of the conductive material 8. Then the resist is selectively etched away to selectively provide (leave) a resist 27 on the conductive material 8 as shown in FIG. 4B.

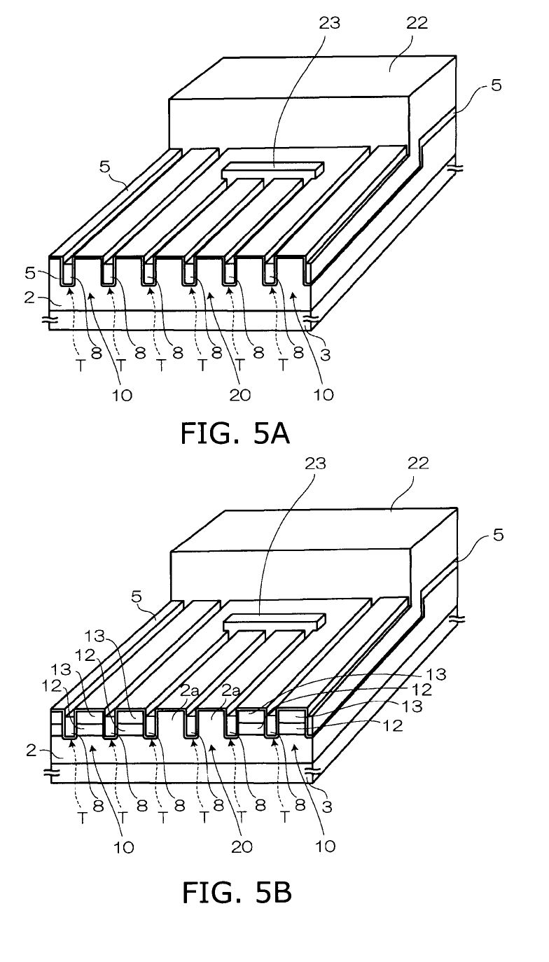

Then the resist 27 is used as a mask to perform selective RIE on the conductive material 8. By this selective RIE, the portion of the conductive material 8 not covered with the resist 27 is removed to expose the insulating film 5 on the semiconductor layer 2 as shown in FIG. 5A. In the trench T, the conductive material 8 in the upper portion of the trench T is removed. The portion of the conductive material covered with the resist 27 is left without being subjected to RIE. Thus, at the end of the trench T of the Schottky barrier diode region 20, an extraction portion 23 integral with the conductive material 8 in the trench T of the Schottky barrier diode region 20 is left on the insulating film 5 of the Schottky barrier diode region 20. The extraction portion 23 extends in a direction generally orthogonal to the extending direction of the trench T. On the other hand, at the end of the trench T of the transistor region 10, an extraction portion 22 integral with the conductive material 8 in the trench T of the transistor region 10 is left on the insulating film 5. The two extraction portions 23 and 22 are insulatively isolated from each other.

Next, ion implantation and diffusion of boron, for example, is performed on the surface portion of the semiconductor layer 2 between the trenches T of the transistor region 10 to form a p-type base region 12 as shown in FIG. 5B. Furthermore, ion implantation and diffusion of arsenic or phosphorus, for example, is performed on the surface portion of the base region 12 to form an n⁺-type source region 13.

The above ion implantation and diffusion is not performed on the semiconductor layer 2 between the trenches T of the Schottky barrier diode region 20. Hence a mesa 2a of the n⁻-type semiconductor layer 2 is provided between the trenches T of the Schottky barrier diode region 20.

Next, a relatively thick insulating film (silicon oxide film) is deposited on the entire surface. Thus the conductive material 8 exposed at the top of the trench T is covered with an insulating film 6 as shown in FIG. 1. Subsequently, the insulating film 6 deposited on the entire surface is selectively etched away. By this selective removal of the insulating film 6, the surface of the source region 13 of the transistor region 10, the surface of the semiconductor layer mesa 2a of the Schottky barrier diode region 20, the surface of the conductive material extraction portion 23 of the Schottky barrier diode region 20, and part of the surface of the extraction portion 22 of the conductive material 8 in the trench T of the transistor region 10 are exposed through the insulating film 6.

Subsequently, a first main electrode 15 is provided on the surface of the transistor region 10 and the Schottky barrier diode region 20. The first main electrode 15 is in contact with the surface of the source region 13, the surface of the semiconductor layer mesa 2a of the Schottky barrier diode region 20, and the surface of the extraction portion 23 of the Schottky barrier diode region 20. The conductive material 8 in the trench T adjacent to the mesa 2a is electrically connected to the first main electrode 15 through the extraction portion 23.

A control electrode 17 is provided on the exposed portion of the extraction portion 22 of the conductive material 8 in the trench T of the transistor region 10. Hence the conductive material 8 in the trench T of the transistor region 10 is electrically connected to the control electrode 17 through the extraction portion 22.

A second main electrode 16 is provided on the surface of the semiconductor layer 3 opposite to the surface where the semiconductor layer 2 is formed.

Next, a comparative example investigated by the inventor in the course of reaching the invention is described.

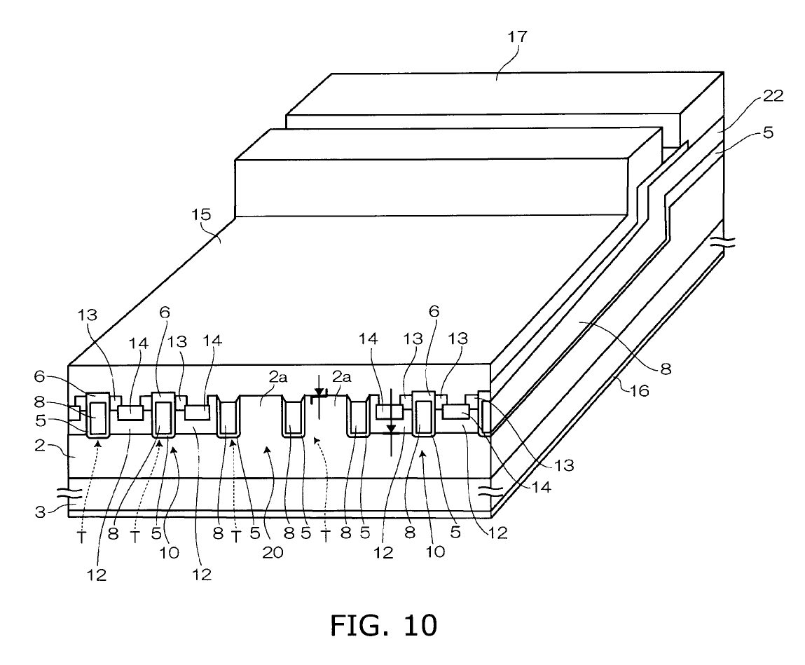

FIG. 10 is a schematic view illustrating the main part of a semiconductor device according to the comparative example.

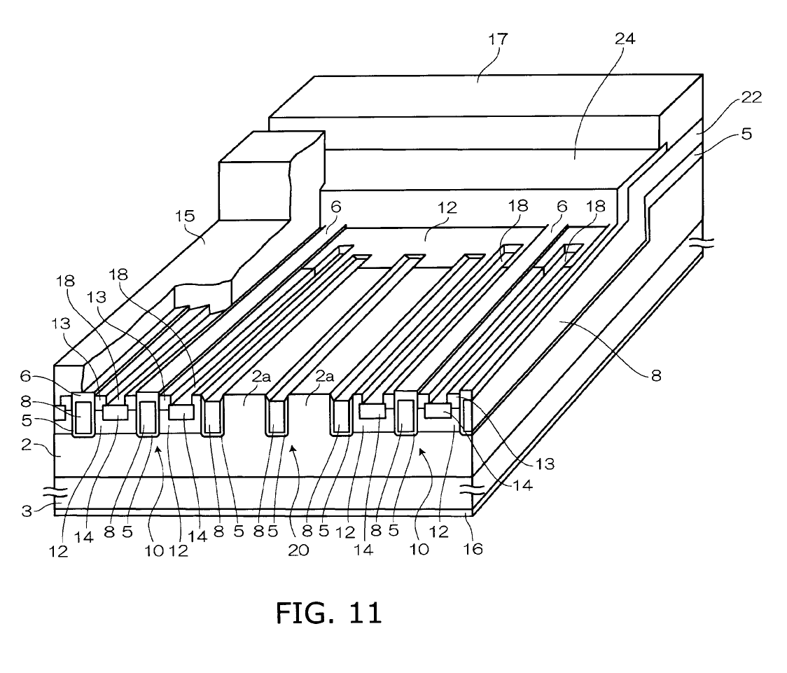

FIG. 11 is the same as FIG. 10 except that the first main electrode 15 is partially removed.

In FIGS. 10 and 11, elements similar to those described above in the example of the invention are marked with the same reference numerals and not described in detail.

In the comparative example, when the conductive material 8 in the trench T adjacent to the semiconductor mesa 2a in the Schottky barrier diode region 20 is connected to the first main electrode 15, the insulating film 6 overlying the conductive material 8 is removed as shown in FIG. 11 by a step separate from the step of forming the MOSFET. More specifically, besides the step of forming the MOSFET, a dedicated step for connecting the conductive material 8 in the trench T of the Schottky barrier diode region 20 to the first main electrode 15 is added, which hampers process cost reduction.

In contrast, in the example of the invention, as described above, the extraction portion 23 for connecting the conductive material 8 of the Schottky barrier diode region 20 to the first main electrode 15 is formed in the course of the step of forming the MOSFET. Thus the increase of process cost due to the addition of steps can be prevented.

Furthermore, in the comparative example, after the insulating film 6 at the top of the trench T adjacent to the semiconductor mesa 2a of the Schottky barrier diode region is removed, the upper portion of the trench T needs to be filled with part of the first main electrode 15. Filling failure in this process may decrease the device performance.

In contrast, in this embodiment, there is no need to fill the trench T with the first main electrode 15. Hence the decrease of device performance due to filling failure described above can be prevented.

Moreover, in the configuration of the comparative example, the semiconductor mesa 2a forms a junction with the p-type base region 12 at the end of the trench T of the Schottky barrier diode region 20. Hence impurity diffusion from the base region 12 into the semiconductor mesa 2a may vary the characteristics of the Schottky barrier diode.

In contrast, in this embodiment, the extraction portion 23 provided at the end of the trench T of the Schottky barrier diode region 20 and the insulating film 25 surrounding the periphery thereof separates the p-type base region 12 from the semiconductor mesa 2a at the end of the trench T. Thus it is possible to prevent such problems as characteristics variation of the Schottky barrier diode due to impurity diffusion from the base region 12 into the semiconductor mesa 2a.

Furthermore, the trench T is formed also below the extraction portion 23, and thereby the Schottky barrier diode region is surrounded by the trench T. This can almost eliminate the impurity diffusion from the base region 12 into the semiconductor mesa 2a.

### Second Example

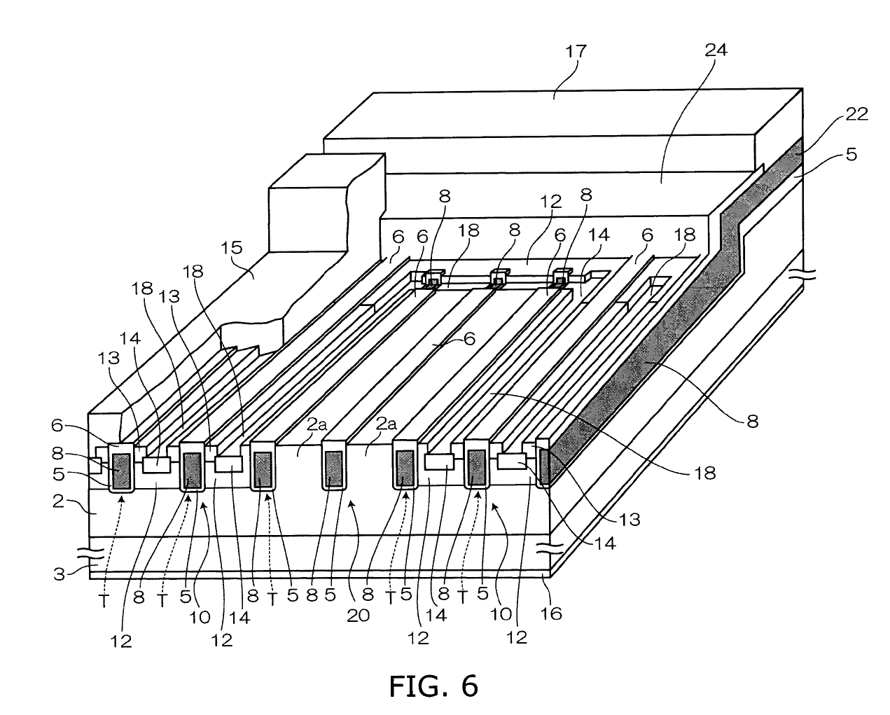

FIG. 6 is a schematic view illustrating the main part of a semiconductor device according to a second example of the invention.

Elements similar to those described above in the first example are marked with the same reference numerals and not described in detail.

This example includes a p⁺-type trench contact region 14 selectively provided in the surface portion of the p-type base region 12, and further includes a contact groove 18 for exposing the trench contact region 14. The contact groove 18 extends generally parallel to the trench extending direction in the transistor region 10, and at the end of the trench T, extends in a direction generally orthogonal to the trench extending direction so as to cross the trench T of the Schottky barrier diode region 20.

By forming the contact groove 18 so as to cross the trench T of the Schottky barrier diode region 20, the conductive material 8 in the trench T adjacent to the semiconductor mesa 2a of the diode region 20 is exposed through the contact groove 18. The contact groove 18 is filled with the first main electrode 15. Thus the conductive material 8 of the Schottky barrier diode region 20 is connected to the first main electrode 15 at the trench end and placed at the source potential.

Furthermore, by filling the contact groove 18 with the first main electrode 15, the trench contact region 14 is also connected to the first main electrode 15 along with the source region 13 and placed at the source potential. Thus the trench contact region 14 formed in the surface portion of the base region 12 is connected to the source electrode. Hence the p-type base region 12 is fixed to the source potential in the OFF state to prevent the parasite bipolar effect in the OFF state and at the switching time. Thus the breakdown voltage of the transistor can be increased.

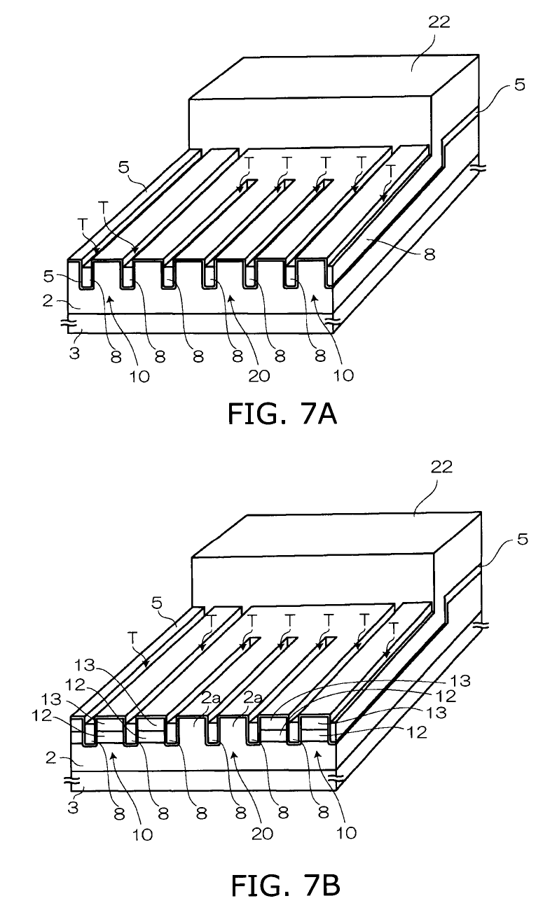

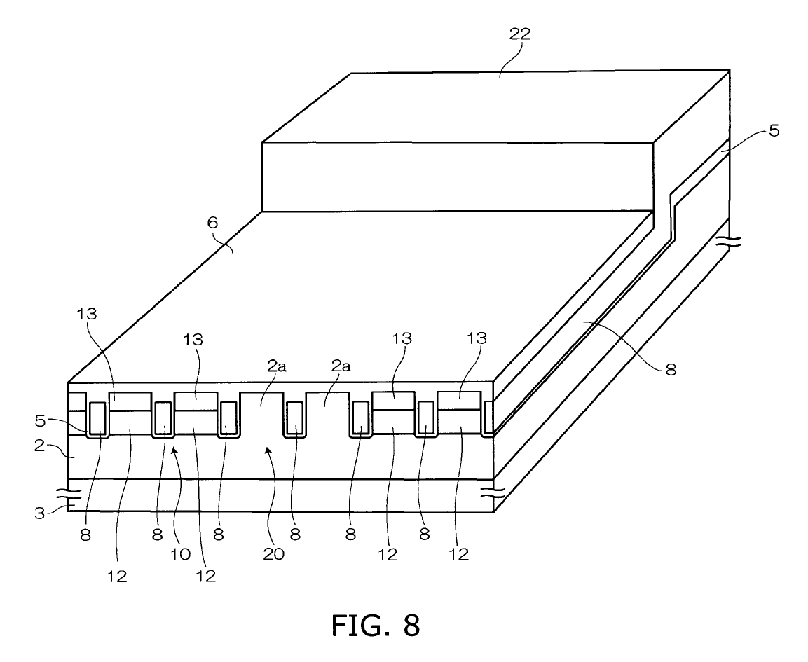

FIGS. 7 and 8 are process cross-sectional views illustrating the main part of a process for manufacturing a semiconductor device according to the second example.

As in the first example described above, a laminated structure of a semiconductor layer 3 made of n⁺-type silicon and a semiconductor layer 2 made of n⁻-type silicon is produced. Then a plurality of trenches T are formed in the surface of the semiconductor layer 2 by e.g. RIE. Subsequently, an insulating film (silicon oxide film) 5 is formed on the surface of the semiconductor layer 2 and the inner wall surface (bottom surface and sidewall surface) of each trench T by e.g. thermal oxidation. Furthermore, a conductive material 8 made of polysilicon is deposited on the entire surface of the semiconductor layer 2 by e.g. CVD so as to fill the trench T.

Then, as shown in FIG. 7A, the conductive material 8 is subjected to RIE. Here, in the second example, in contrast to the first example, the portion of the conductive material to serve as an extraction portion is not left at the trench end of the Schottky barrier diode region 20, but this portion of the conductive material is also removed.

Next, ion implantation and diffusion of boron, for example, is performed on the surface portion of the semiconductor layer 2 between the trenches T of the transistor region 10 to form a p-type base region 12 as shown in FIG. 7B. Furthermore, ion implantation and diffusion of arsenic or phosphorus, for example, is performed on the surface portion of the base region 12 to form an n⁺-type source region 13.

The above ion implantation and diffusion is not performed on the semiconductor layer 2 between the trenches T of the Schottky barrier diode region 20. Hence a mesa 2a of the semiconductor layer 2 is provided between the trenches T of the Schottky barrier diode region 20.

Next, as shown in FIG. 8, a relatively thick insulating film (silicon oxide film) 6 is deposited on the entire surface. Subsequently, the insulating film 6 deposited on the entire surface is selectively etched away. By this selective removal of the insulating film 6, the surface of the source region 13 of the transistor region 10, the surface of the semiconductor layer mesa 2a of the Schottky barrier diode region 20, and part of the surface of the extraction portion 22 of the conductive material 8 in the trench T of the transistor region 10 are exposed through the insulating film 6.

Then, as shown in FIG. 6, a contact groove 18 is formed to selectively expose the surface of the base region 12 through the source region 13 and to partially expose the conductive material 8 at the end of the trench T of the Schottky barrier diode region 20. Subsequently, ion implantation and diffusion of boron, for example, is performed on the exposed surface of the base region 12 to form a p⁺-type trench contact region 14.

Subsequently, a first main electrode 15 is provided on the surface of the transistor region 10 and the Schottky barrier diode region 20. The first main electrode 15 is in contact with the surface of the source region 13, the surface of the trench contact region 14, the surface of the semiconductor layer mesa 2a of the Schottky barrier diode region 20, and the surface of the conductive material 8 exposed at the trench end of the Schottky barrier diode region 20. A control electrode 17 is provided on the exposed portion of the extraction portion 22 of the conductive material 8 in the trench T of the transistor region 10.

Also in this example, in the course of the step of forming the MOSFET, that is, simultaneously with the step of forming a contact groove 18 of the MOSFET, the conductive material 8 is exposed at the trench end of the Schottky barrier diode region 20, and then the conductive material 8 in the trench of the Schottky barrier diode region 20 is connected to the first main electrode 15 along with the source region 13 and the trench contact region 14. Thus the increase of process cost due to the addition of steps can be prevented.

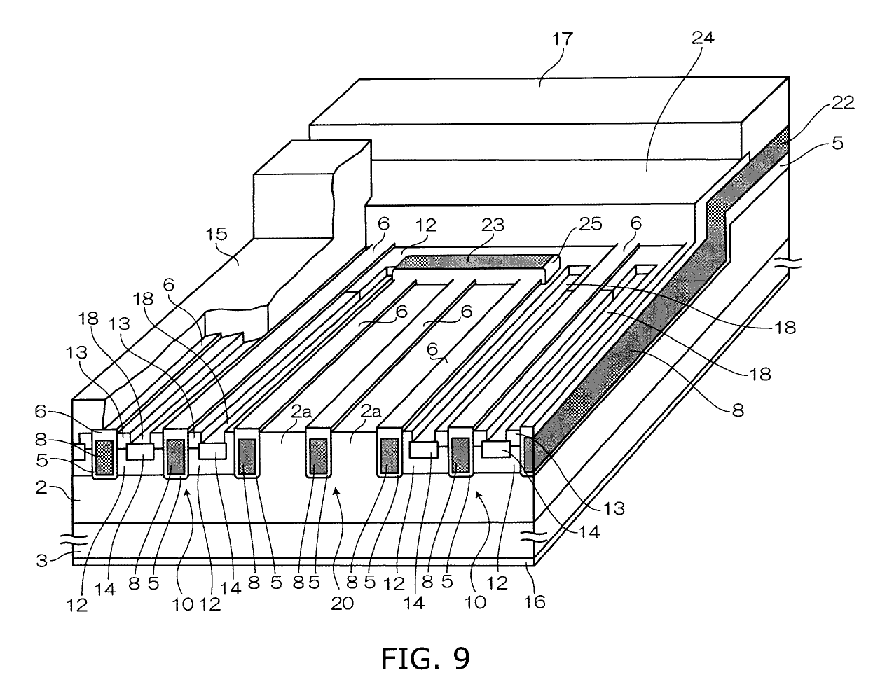

FIG. 9 is a schematic view showing the configuration where a trench contact region 14 is provided in the semiconductor device according to the first example described above.

Also in this case, the extraction portion 23 for connecting the conductive material 8 of the Schottky barrier diode region 20 to the first main electrode 15 is formed in a common process of manufacturing a MOSFET having a trench contact region. That is, a process separate from the MOSFET process is not required for connecting the conductive material 8 of the Schottky barrier diode region 20 to the first main electrode 15. Thus the increase of process cost due to the addition of steps can be prevented.

Next, the relationship between the width of the semiconductor mesa 2a (the distance between the trenches T sandwiching the mesa 2a) and the output charge in a Schottky barrier diode is described.

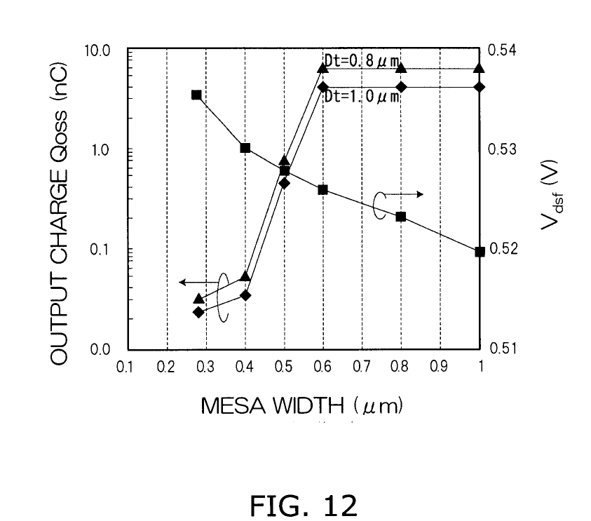

FIG. 12 is a graph showing the relationship between the width of the semiconductor mesa 2a (the distance between the trenches T sandwiching the mesa 2a) and the output charge of a Schottky barrier diode.

The horizontal axis represents the width (μm) of the semiconductor mesa 2a. The left vertical axis represents the output charge Qoss (nC) upon application of a drain-source voltage of Vds=19 V. The right vertical axis represents the diode forward voltage Vdsf (V) for a forward current of 12 A. “Dt” in the graph represents the trench depth.

As seen in the result shown in FIG. 12, in both cases of trench depth Dt, 0.8 μm and 1.0 μm, the output charge Qoss is significantly reduced when the mesa width is less than 0.6 μm.

From the viewpoint of reducing the increase of output charge and the increase of the aspect ratio of the trench, the mesa width W is preferably designed depending on the trench depth Dt so as to satisfy the following formula, for example:
W<Dt×0.2+0.3 (each in μm)

For example, for a trench depth of Dt=1.0 (μm), a preferable mesa width W satisfies W<0.5 (μm).

The embodiment of the invention has been described with reference to examples. However, the invention is not limited thereto, but may be variously modified within the scope of the invention.

The position where part of the conductive material 8 in the trench T of the Schottky barrier diode region 20 is in contact with the first main electrode 15 is not limited to the trench end. Furthermore, they may be in contact with each other at a plurality of positions.

In the surface portion of the semiconductor layer 2 of the transistor region 10, the base region 12 and the source region 13 may be formed before the trench T is formed.

Only the low-voltage MOSFET for use in a non-isolated step-down DC-DC converter has been described herein. However, the invention is also applicable to high-voltage MOSFETs. For example, the drift layer herein is made of an n⁻-type semiconductor layer. However, the drift layer may be modified. The invention is also effectively applied to a super junction structure where a p-type semiconductor region having a high aspect ratio is connected to the p-type base region 12.

The invention is not limited to Si-based devices, but is also applicable to devices based on SiC or GaN. While the n-channel MOSFET has been described herein, the invention is also applicable to p-channel MOSFETs. The source electrodes 15 divided into a number of portions by the gate electrode 17 may be interconnected by a metal layer formed on the gate electrode 17 via an insulating film.

In this invention, the trenches T are arranged in parallel both in the transistor region and in the Schottky barrier diode region. This is because the parallel arrangement in the transistor region is superior in trade-off characteristics between the gate capacitance and the ON resistance. The arrangement is effective for cases requiring high-speed switching characteristics. However, when the MOSFET requires low ON resistance, the arrangement of trenches T is not limited to the above parallel arrangement, but the trenches T may be arranged, as viewed from above the semiconductor major surface, in a mesh, offset mesh, or houndstooth check configuration, which allows the trenches T to be arranged with higher density. The Schottky barrier diode region may also be based on the above arrangement of trenches T depending on the requirements of the diode forward voltage drop Vsdf and the forward current If.

1. A semiconductor device comprising:
a semiconductor layer of a first conductivity type;
a plurality of trenches provided on a major surface side of the semiconductor layer;
an insulating film provided on an inner wall surface and on top of the trench;
a conductive material surrounded by the insulating film and filling the trench;
a first semiconductor region of a second conductivity type provided between the trenches;
a second semiconductor region of the first conductivity type provided in a surface portion of the first semiconductor region;
a mesa of the semiconductor layer provided between the trenches of a Schottky barrier diode region adjacent to a transistor region including the first semiconductor region and the second semiconductor region;
a control electrode connected to the conductive material filling the trench of the transistor region; and
a main electrode provided in contact with a surface of the first semiconductor region, the second semiconductor region, a surface of the mesa and a part of the conductive material filling the trench of the Schottky barrier diode region, the part being exposed through the insulating film.

2. The semiconductor device according to claim 1, wherein the conductive material exposed through the insulating film and connected to the main electrode extends in a direction crossing the trench of the Schottky barrier diode region.

3. The semiconductor device according to claim 2, wherein the conductive material filling the trench of the transistor region is connected to an extraction portion provided at end of the trench extending direction, the control electrode is provided in contact with the extraction portion.

4. The semiconductor device according to claim 3, wherein the extraction portion is integral with the conductive material filling the trench of the transistor region.

5. The semiconductor device according to claim 2, wherein the conductive material filling the trench of the Schottky barrier diode region is connected to an extraction portion provided at end of the trench extending direction, the main electrode is provided in contact with the extraction portion.

6. The semiconductor device according to claim 5, wherein the extraction portion is integral with the conductive material filling the trench of the Schottky barrier diode region.

7. The semiconductor device according to claim 5, wherein the extraction portion and an insulating film surrounding the periphery of the extraction portion separate the first semiconductor region from the mesa.

8. The semiconductor device according to claim 2, wherein the main electrode forms an ohmic contact with the surface of the second semiconductor region.

9. The semiconductor device according to claim 2, wherein the main electrode forms a Schottky contact with the surface of the mesa.

10. The semiconductor device according to claim 2, wherein the plurality of trenches extend parallel to each other.

11. The semiconductor device according to claim 1, further comprising:
a trench contact region of the second conductivity type selectively provided in the surface portion of the first semiconductor region; and
a contact groove that exposes the trench contact region and extends in the direction crossing the trench of the Schottky barrier diode region to expose the conductive material of the Schottky barrier diode region through the insulating film,
wherein the contact groove is filled with the main electrode, and the exposed conductive material is connected to the main electrode.

12. The semiconductor device according to claim 11, wherein the main electrode is in contact with the trench contact region, the potential of the first semiconductor region is fixed to the potential of the main electrode.

13. The semiconductor device according to claim 11, wherein the contact groove extends substantively parallel to the trench extending direction in the transistor region.

14. The semiconductor device according to claim 11, wherein the conductive material filling the trench of the transistor region is connected to an extraction portion provided at end of the trench extending direction, the control electrode is provided in contact with the extraction portion.

15. The semiconductor device according to claim 14, wherein the extraction portion is integral with the conductive material filling the trench of the transistor region.

16. The semiconductor device according to claim 11, wherein the main electrode forms an ohmic contact with the surface of the second semiconductor region.

17. The semiconductor device according to claim 11, wherein the main electrode forms a Schottky contact with the surface of the mesa.

18. The semiconductor device according to claim 11, wherein the plurality of trenches extend parallel to each other.

19. A method for manufacturing a semiconductor device comprising:
forming a plurality of trenches on a major surface side of a semiconductor layer of a first conductivity type;
forming a first insulating film on an inner wall surface of the trench;
burying a conductive material in the trench with the first insulating film formed on the inner wall surface;
forming a first semiconductor region of a second conductivity type between the trenches of a transistor region;
forming a second semiconductor region of the first conductivity type in a surface portion of the first semiconductor region;
partially exposing the conductive material of a Schottky barrier diode region adjacent to the transistor region and forming a second insulating film overlying the conductive material in the trench; and
forming a main electrode in contact with a surface of the second semiconductor region, the partially exposed conductive material in the Schottky barrier diode region, and the semiconductor layer between the trenches of the Schottky barrier diode region.

20. A method for manufacturing a semiconductor device comprising:
forming a plurality of trenches on a major surface side of a semiconductor layer of a first conductivity type;
forming a first insulating film on an inner wall surface of the trench;
burying a conductive material in the trench with the first insulating film formed on the inner wall surface;
forming a first semiconductor region of a second conductivity type between the trenches of a transistor region;
forming a second semiconductor region of the first conductivity type in a surface portion of the first semiconductor region;
forming a second insulating film overlying the conductive material in the trench;
forming a contact groove crossing the trench of a Schottky barrier diode region adjacent to the transistor region so as to expose the first semiconductor region through the second semiconductor region and to expose the conductive material of the Schottky barrier diode region through the second insulating film; and
forming a main electrode that fills the contact groove and is in contact with a surface of the semiconductor layer between the trenches of the Schottky barrier diode region.
